(19) United States
(12) Patent Application Publication
(10) Pub. No.: US 2018/0040794 A1
(43) Pub. Date: Feb. 8, 2018

(54) Realizing the Dream of Green Energy and Making the Impossible Possible

(71) Applicant: Hisham Tarabishi, Pittsburgh, PA (US)

(72) Inventor: Hisham Tarabishi, Pittsburgh, PA (US)

(21) Appl. No.: 15/406,998

(22) Filed: Jan. 16, 2017

Related U.S. Application Data
(60) Provisional application No. 62/494,312, filed on Aug. 4, 2016.

(51) Int. Cl. H01L 35/28; F24J 2/50; F24J 2/46; F03G 6/04; F24J 2/10

(52) U.S. Cl. CPC H01L 35/28; F03G 6/04; F24J 2/10; F24J 2/4649; F24J 2/50; F24J 2002/0405

(57) ABSTRACT

An apparatus for storing and/or converting solar energy into a mechanical and/or electrical energy product in a continuous manner, twenty-four hours a day. The apparatus includes an enclosed volume chamber having a wall formed from transparent material capable of allowing solar energy beams to enter into the chamber, the wall of the chamber having a reflective inner surface for trapping and reflecting the solar energy beams within the chamber, a heat absorbing member located within the chamber for receiving at least a portion of the solar energy beams, an inlet for feeding air into the chamber wherein the air becomes heated, an outlet for allowing the heated air to exit the chamber, and a conversion device for cooperating with the outlet for receiving the heated air and for converting the heated air to mechanical and/or electrical energy. The conversion device can be a plurality of thermophotovoltaic cells or a turbine.

### CROSS REFERENCE TO RELATED APPLICATIONS

This application claims priority to U.S. Provisional Patent Application No. 62/494,312, filed on Aug. 4, 2016, which is incorporated herein by reference.

### BACKGROUND OF THE INVENTION

### Field of the Invention

The invention relates generally to an apparatus for converting solar energy into a usable energy product that can be used continuously and endlessly twenty-four hours a day, and, more particularly, to an economical system for converting a high percentage of sunlight radiant energy to electricity with negligible optical losses utilizing a one-way mirror system to collect the solar energy and trapping the energy within an enclosed chamber. This energy can be used in combination with thermophotovoltaic cells or in combination with a turbine to simultaneously produce mechanical and/or electrical energy on a continuous, sustainable cycle with zero carbon emission.

### Description of Related Art

Solar energy has been available as a source of power for more than 4.5 billion years. For centuries, inventors have been devising various means to harness this energy. As far back as the third century B.C., records indicate that the Greek and Roman armies used “burning mirrors” to focus sunlight as weapons of war to ignite fires and to burn sails of enemy warships.

Solar energy provides the world either directly or indirectly with the majority of its energy. Solar energy is a renewable energy source having vast potential. Although solar energy is abundant, a major drawback is that it is diffuse and not available at all hours. Solar energy can be affected by the time of the day, the seasons, and the changing sun path in the sky as the earth's axis is not at a right angle to the sun, but it is tilted away at an angle of 23.5°.

For decades, inventors have tried various systems for harnessing this incredible energy source. For example, U.S. Pat. Nos. 3,988,166; 4,286,581; 5,275,149; and 4,038,971 have sought to control and convert this energy into a cost-effective usable form. Unfortunately, these systems are cumbersome, expensive to manufacture and maintain, expensive to operate, and yield little in terms of usable and convertible energy.

The article entitled “Principles of Solar Thermal Conversion” by R.H.B. Exell, 2000. King Mongkut's University of Technology Thonburi, also discusses, in terms of academic interest only, of trapping solar radiation in an enclosed volume with perfectly reflecting walls at the temperature of the sun, i.e., approximately 5800 K and the need for a parabolic concentrator that focuses direct solar radiation into the enclosed volume. The article further discusses that if solar energy were to be used on a large scale, since solar energy is theoretically a very high temperature resource, one should try to harness it at this very high temperature for efficient conversion and then use the waste heat for low temperature purposes instead of downgrading the solar energy with low temperature collectors at the start. This article recites a theory for what is desired in this technology, but provides no direction as to how it can be achieved.

U.S. Pat. Nos. 7,640,931 and 8,413,442 to Tarabishi, the entirety of which are incorporated by reference thereto, are directed to solar collecting systems which can concentrate or condense solar energy at a fixed, stationary focal point to economically harness the sun's energy into a manageable and convertible form.

In particular, U.S. Pat. No. 7,640,931 teaches a system for tracking the sun and maintaining a constant fixed focal point or sub-focal point to at least partially condense the sun's rays into a high-energy beam that can be redirected to a predetermined location for generating electrical power, heat energy, steam, and the like. U.S. Pat. No. 8,413,442 utilizes the collecting and condensing system from U.S. Pat. No. 7,640,931 in combination with one or more enclosed volume chambers connected in series to convert the energy into a mechanical and/or electrical energy product on a sustainable cycle.

Various types of glass that are capable of withstanding high temperatures and harsh environmental conditions are known. Examples of these types of glass include borosilicate glass and Vycor® glass, which is high temperature glass having a 96% SiO2 content and is produced by Corning, Incorporated. Borosilicate glass is a type of glass with silica and boron trioxide, has a low coefficient of thermal expansion, and is resistant to thermal shock. This type of glass is used extensively in glassblowing and lampworking and is often referred to as “hard glass” and has a higher melting point (approximately 3,000° F./1648° C.) than “soft glass”. Vycor® glass also has a low coefficient of thermal expansion and good thermal shock resistance. This type of glass can be used at high continuous operating temperatures of up to 900° C. or 1700-2200° F. and can withstand harsh environmental conditions like acids, water, steam, and low and high temperatures. Vycor® glass also has high ultraviolet and visible transmittance.

One-way mirrors are also known and are commonly used in law enforcement. One-way mirrors, which also can be called two-way mirrors, is a mirror that is partially reflective and partially transparent. When one side of the mirror is brightly lit and the other is dark, it allows viewing from the darkened side, but not vice versa. The glass is coated with, or has encased within, a thin and almost transparent layer (usually aluminum). The optical properties of the mirror, such as reflectance, transmittance, and absorption, can be tuned by changing the thickness of the reflecting layer.

Photovoltaic cells are used to convert light into electricity. Thermophotovoltaic cells use different technology to produce electricity. “Thermo” means heat and, therefore, these cells convert heat into electricity. Thermophotovoltaic cells use semiconductors, which are designed for a specific wavelength and invisible light, like infrared rays, released by hot objects. This way of generating electricity is very neat and clean. Another advantage to the use of thermophotovoltaic cells is that they do not require much maintenance to work and do not produce any by-product that can harm the environment. For this reason, thermophotovoltaic cells are “clean” sources of energy. In the past, thermophotovoltaic cell technology has been expensive, however, recent advance by companies such as IMEC have made the use of thermophotovoltaic cells affordable and relatively simple.

The use of thermophotovoltaic cell technology in an efficient and cost-effective manner in combination with the collecting and condensing system from U.S. Pat. No. 7,640,931 and is disclosed in U.S. Pat. No. 9,252,701 to Tarabishi, the entirety of which is incorporated by reference thereto. This system is capable of converting up to 95% of sunlight to radiant energy to electricity simultaneously producing AC and DC energy using the proper level of condensed solar energy temperature. However, the collecting and condensing system requires the use of several working parts in order to properly collect and to condense the radiant energy and supply the energy into the chamber for converting the energy into electricity.

The present invention is directed to a system that uses a creative and cost effective technique to collect, trap, and condense solar energy within an enclosed volume chamber formed from inexpensive and readily available materials. The present invention is also directed to a system that collects and condenses sun rays into thermal energy that can be used continuously and endlessly twenty-four hours a day year round. This collecting system can convert the solar energy into a heated product that can be used in combination with thermophotovoltaic cells and/or with a turbine to generate electrical and/or mechanical energy. The present invention can also be downgraded in size so that it can be used for home use or upgraded in size for use in industrial environments.

### SUMMARY OF THE INVENTION

The system of the present invention combines the power of simplicity and applies it to the complex issue of solar energy. The system of the present invention uses readily available and economically desirable materials to collect, trap, and condense solar energy and then convert this energy into electrical and/or mechanical energy. The system can be used continuously and endlessly and can be sized for use in homes or industrial applications. The system can also rely on solar short waves to operate. The system of the present invention also has minimal optical losses and is capable of being used in combination with thermophotovoltaic cell technology in an efficient and cost-effective manner to convert the sun's energy into electricity.

According to one aspect, the invention is directed to an apparatus for collecting, trapping, storing, and/or converting solar energy into a mechanical and/or electrical energy product. The apparatus includes an enclosed volume chamber having a wall formed from transparent material capable of allowing solar energy beams to enter into the enclosed volume chamber, the wall of the enclosed volume chamber having a reflective inner surface for trapping and reflecting the solar energy beams within the enclosed volume chamber. A heat absorbing member is located within the enclosed volume chamber for receiving at least a portion of the solar energy beams entering into and/or reflecting throughout the enclosed volume chamber. The apparatus also includes at least one inlet for feeding air into the chamber wherein the air becomes heated and at least one outlet for allowing the heated air to exit the chamber, and a conversion device configured for cooperating with the outlet for receiving the heated air and for converting the heated air to mechanical and/or electrical energy.

According to one embodiment, the transparent material comprises a one-way mirror, such as a high-temperature glass including a reflective inner surface facing the enclosed volume chamber. According to one embodiment, the high-temperature glass is capable of withstanding temperatures of at least 900° C. on a continuous basis.

The enclosed volume chamber includes an open space containing air located between the inner surface of the wall and the heat absorbing member, wherein the solar beams heat the air contained within the open space and the air fed into the chamber. At least a portion of the air fed into the chamber can be fed directly into the heat absorbing member.

According to one embodiment, the enclosed volume chamber can be in the shape of a dome and up to 50% of the wall of the enclosed volume chamber is formed from the transparent material. According to another embodiment, even more than 50% of the wall of the enclosed volume chamber can be formed from the transparent material.

The inner surface of the wall of the enclosed volume chamber can include a mirrored surface and/or a reflective film configured to reflect the solar energy beams. The enclosed volume chamber can also include a mirror floor configured to diffuse and reflect the solar energy beams.

The enclosed volume chamber can be mounted on a base member and a portion of the heat absorbing member can be located within the base member. The at least one inlet for feeding air into the chamber and the at least one outlet for allowing the heated air to exit the chamber can be located within the portion of the heat absorbing member located within the base member. In addition to or alternatively, the at least one inlet for feeding air into the chamber and the at least one outlet for allowing the heated air to exit the chamber can be located within the wall of the enclosed volume chamber.

According to one embodiment, the conversion device comprises a plurality of thermophotovoltaic cells which receive the heated air exiting the enclosed volume chamber. According to one design, the plurality of thermophotovoltaic cells can be in the shape of a cone or a funnel and wherein thermophotovoltaic cells have a front surface facing an inside cavity of the cone or funnel. The heated air applied to the thermophotovoltaic cells can cause the cells to become excited into DC electricity and the apparatus further includes a wiring system associated with the thermophotovoltaic cells for carrying the DC electricity to a target location for use. The apparatus can further include at least one cooling tube including coolant extending about an outer surface of the cone or funnel of thermophotovoltaic cells for cooling the thermophotovoltaic cells.

According to another embodiment, the conversion device can include a turbine connected to a generator for converting the heated air exiting the enclosed volume chamber into AC electricity.

The apparatus can also include at least one pump for feeding the air into the enclosed volume chamber. A heat sensor can be provided for monitoring a temperature level of the enclosed volume chamber. The heat sensor can be in communication with the at least one pump to increase or decrease the flow of air into the enclosed volume chamber in order to adjust the temperature within the enclosed volume chamber and to provide a continuous supply of energy.

According to still another aspect of the invention, a system for collecting and converting solar energy into a mechanical and/or electrical energy product includes an enclosed volume chamber having a wall formed from transparent material capable of allowing solar energy beams to enter into the enclosed volume chamber, the wall of the enclosed volume chamber having a reflective inner surface for trapping and reflecting the solar energy beams within the enclosed volume chamber. A heat absorbing member is located within the chamber for receiving at least a portion of the solar energy beams entering into and/or reflecting throughout the enclosed volume chamber. At least one inlet is provided for feeding air into the chamber wherein the air becomes heated and at least one outlet is provided for allowing the heated air to exit the chamber. The apparatus further includes at least one conversion device comprising at least one of a plurality of thermophotovoltaic cells and a turbine which convert the heated air into one of a mechanical and/or electrical energy product.

According to one embodiment, the thermophotovoltaic cells can be formed from gallium, antimonide, or germanium; however, any known material can be used to form the thermophotovoltaic cells. The plurality of thermophotovoltaic cells can comprise an array formed from multiple frequency cells to capture rays emitting along the entire spectrum. The array can produce at least 5-6 watts per square centimeter. The thermophotovoltaic cells can have an operating temperature within the range of 900-1200° C.

The air fed into the chamber can be a low pressure air source fed by any known device, such as tubing and the like, at ambient temperature as long as the air has sufficient force to drive the thermal energy out of the chamber to the cone of thermophotovoltaic cells or to the turbine.

According to one embodiment, the heat absorbing member can be formed from a combination of heat absorbing materials having differing heat capacity levels, and the chamber is capable of storing heat energy for up to several weeks, or even several months, depending upon the rate of depletion and/or the amount of usage of the heat energy as well as the size of the heat absorbing member.

A plurality of enclosed volume chambers can be provided in series and any stored thermal energy can be fed to a second of the series of enclosed volume chambers to enable the subsequent enclosed volume chamber to increase and/or maintain a predetermined level of heat energy in the second chamber.

This system is self-sustaining and would achieve a powerful electricity output and/or mechanical output, allowing the highest conversion of sunlight energy to electricity at a zero carbon emission. Efficiency becomes of no concern. Full implementation of all of the system stages, results in the cost of kwh to be less than one cent, which would make carbon capture and storage affordable, as well as water distillation and hydrogen production. Widespread use of the system will significantly contribute to the fight against global warming and the greenhouse effect, provide cheap carbon-free chemical fuel, and solve the clean water shortage. A third industrial revolution is possible using solar energy.

### BRIEF DESCRIPTION OF THE DRAWING(S)

FIG. 1 shows a side schematic view of an apparatus for collecting, trapping, and converting solar energy into a mechanical and/or electrical energy product including an enclosed chamber according to another embodiment of the present invention;

FIG. 2 shows a front perspective view of a thermophotovoltaic collection and converting cone that can be coupled to the enclosed chamber of FIG. 1 for converting the heat energy into an electrical energy product in accordance with one embodiment of the present invention; and

FIG. 3 shows a schematic representation of a thermophotovoltaic cell which can be used in the solar energy converting apparatus.

### DESCRIPTION OF THE INVENTION

For purposes of the description hereinafter, the terms “upper”, “lower”, “right”, “left”, “vertical”, “horizontal”, “top”, “bottom”, “lateral”, “longitudinal”, and derivatives thereof shall relate to the invention as it is oriented in the drawing figures. However, it is to be understood that the invention may assume various alternative variations, except where expressly specified to the contrary. It is also to be understood that the specific devices illustrated in the attached drawings, and described in the following specification, are simply exemplary embodiments of the invention. Hence, specific dimensions and other physical characteristics related to the embodiments disclosed herein are not to be considered as limiting.

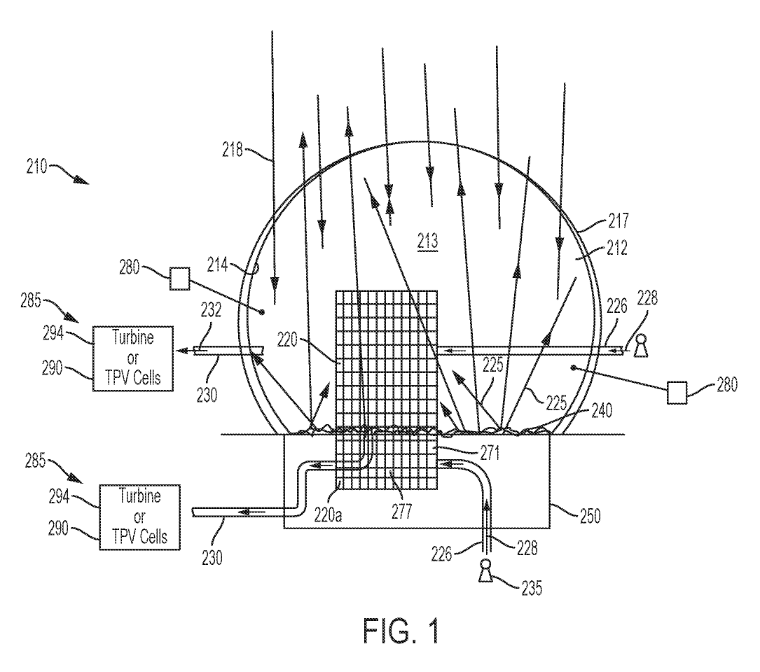

Reference is now made to FIG. 1 which shows a side schematic view of an apparatus, generally indicated as 210 for collecting, trapping, and converting solar energy into a mechanical and/or electrical energy product. The apparatus includes an enclosed volume chamber 212 having a wall 217 formed from transparent material capable of allowing solar energy beams 218 to enter into the interior chamber 113 of the enclosed volume chamber 112. The wall 217 of the enclosed volume chamber 212 has a reflective inner surface 214 for trapping and reflecting the solar energy beams 218 within the enclosed volume chamber 212.

A heat absorbing member 220 is located within the enclosed volume chamber 212 for receiving at least a portion of the solar energy beams 218 entering into and/or reflecting throughout the enclosed volume chamber 212 causing the heat absorbing member 220 to heat up. The heat absorbing member 220 can be formed as a series or block of bricks 277 which are positioned with spacing 278 therebetween to increase the exposed surface area of the bricks 277. Air 228 fed into the chamber 212 can be ambient air, which is injected into the spacing 278 between the bricks 277 within the block and moves through the spaces 278 of the bricks 277 so that the air 228 quickly contacts the surface areas of the solar heated bricks 277 and quickly heats up. The heat absorbing member 220 is capable of withstanding temperatures in excess of 1000° C. The chamber 212 and its contents are capable of storing heat energy for up to several months depending upon the rate of depletion and/or the amount of usage of the heat energy and the size of the storage/chamber 212. This would be desirable in areas of the world where there are prolonged periods where sunlight is absent or there is very low sun intensity.

With continuing reference to FIG. 1, the apparatus 210 also includes at least one inlet 226 for feeding the air 228 into the enclosed volume chamber 212 wherein the air becomes heated. At least one outlet 230 is provided for allowing the heated air 232 to exit the chamber 212. A conversion device, generally indicated as 285, is provided which is configured for cooperating with the at least one outlet 230 for receiving the heated air 232 and for converting the heated air 232 to mechanical and/or electrical energy.

According to one embodiment, the wall 217 of the chamber 212 can be formed from a high-temperature glass capable of withstanding high temperatures such as at least 900° C. and harsh environmental conditions. Examples of the glass include borosilicate glass or Vycor® glass, which is high temperature glass having a 96% SiO2 content and is produced by Corning, Incorporated. Borosilicate glass has a low coefficient of thermal expansion and is resistant to thermal shock and has a high melting point (approximately 3,000° F./1648° C.). Vycor® glass also has a low coefficient of thermal expansion and good thermal shock resistance. This type of glass can be used at high continuous operating temperatures of up to 900° C. or 1700-2200° F., and can withstand harsh environmental conditions like acids, water, steam, and low and high temperatures. Vycor® glass also has high ultraviolet and visible transmittance.

The wall 217 of the chamber can also include a reflective inner surface 214 facing the interior portion 213 of the enclosed volume chamber 212. According to one embodiment, the reflective inner surface 214 can be formed by incorporating a film of aluminum such that the glass or wall 217 functions as a one-way mirror, thus, trapping the solar energy beams 218 in the chamber and reflecting them as heat energy 225 such that they move through the interior portion 213 of the chamber 212. It can be appreciated that some of the reflected beams will escape through the wall 217 of the chamber as lost solar energy beams 227.

The interior portion 213 of the enclosed volume chamber 212 includes an open space containing air located between the inner surface 214 of the wall 217 and the heat absorbing member 220. The solar beams 218 can be used to heat the air contained within the open space as well as the air 228 being fed into the chamber 212. At least a portion of the air 228 fed into the chamber can be fed directly into the heat absorbing member 220.

According to one embodiment, the enclosed volume chamber 212 can be in the shape of a dome and up to 50% of the wall 217 of the enclosed volume chamber 212 can formed from the high temperature glass. According to another embodiment, even more than 50% of the wall 217 of the enclosed volume chamber 212 can be formed from the high temperature glass.

The enclosed volume chamber 212 can also include a mirrored floor 240 that is configured or shaped to diffuse and reflect the solar energy beams 218 as solar heat energy 225.

With continued reference to FIG. 1, the enclosed volume chamber 212 can be mounted on a base member 250. The base member 250 can include a storage chamber configured for containing or holding at least a portion, as indicated by 220a, of the heat absorbing member 220. The at least one inlet 226 for feeding air 228 into the chamber 212 and the at least one outlet 230 for allowing the heated air 232 to exit the chamber 212 can be located within the portion 220a of the heat absorbing member 220 located within the base member 250. In addition to or alternatively, the at least one inlet 226 for feeding air 228 into the chamber 212 and the at least one outlet 230 for allowing the heated air 232 to exit the chamber 212 can extend through the wall 217 of the enclosed volume chamber 212.

Referring still to FIG. 1, the apparatus can also include at least one pump 235 for feeding the air 228 into the enclosed volume chamber 212. A heat sensor 280 can be provided for monitoring a temperature level of the enclosed volume chamber. The heat sensor 280 can be in communication with the at least one pump 235 to increase or decrease the flow of air 228 into the enclosed volume chamber 212 in order to adjust the temperature within the enclosed volume chamber 212. For example, if the temperature within the chamber 212 exceeds a predetermined temperature, such as 1000° C., the flow of the air 228 entering into the chamber can be increased, which, in turn, acts as a cooling agent to cool the heat absorbing member 220 and force the heated air 232 out of the chamber at a faster rate, thus, lowering the temperature of the chamber 212. If the temperature level within the chamber falls below a predetermined temperature, such as 900° C., the flow of the air 228 entering into the chamber 212 can be reduced or slowed, resulting in a rise in temperature within the chamber 212 due to the reduction in cool air and/or a reduction of flow of heated air 232 out of the chamber 212.

It can be appreciated that various sizes of heat absorbing members 220 may be used in the apparatus 200 of the invention depending upon the amount of electricity production required. It can also be appreciated that the size of the heat absorbing member 220 affects the amount of thermal energy held therein and can be a black body that is placed in the center of the enclosed chamber 212. The heat sensor 280, in combination with the at least one pump 235 and the heat absorbing member 220, can cooperate together so that the system can run continuously for twenty-four hours all year long.

According to one embodiment, the heat absorbing member 220 can be formed from a combination of heat absorbing materials having differing heat capacity levels, and the chamber 212 is capable of storing heat energy for up to several months, depending upon the rate of depletion and/or the amount of usage of the heat energy. For example, the heat absorbing member 220 can be formed from a combination of heat absorbing materials, such as cast iron, magnesium, mixed ceramic material, concrete, and the like, having differing heat capacity levels and differing heat conductive properties.

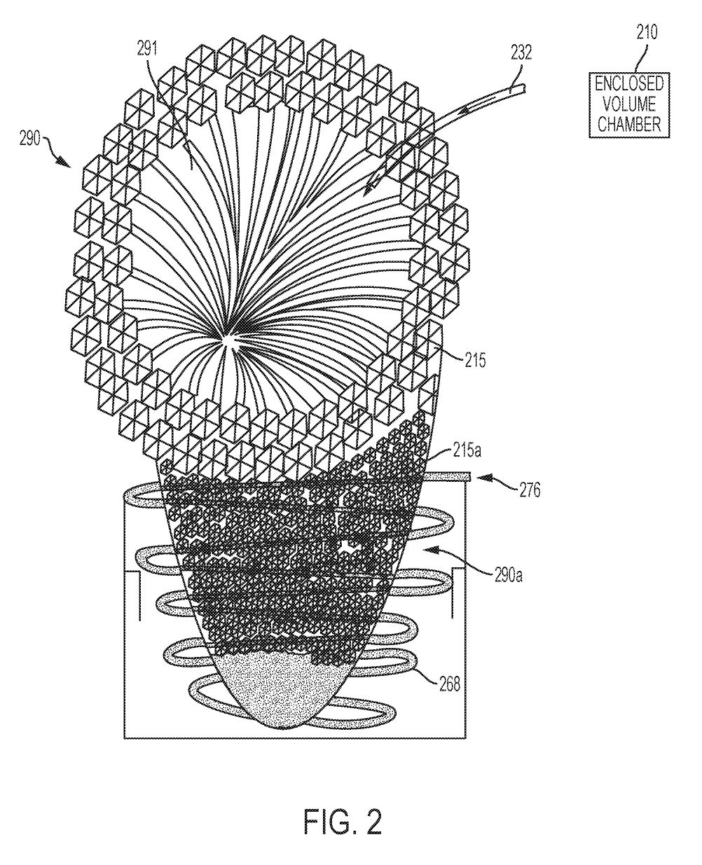

Reference is now made to FIG. 2, which illustrates one embodiment wherein the conversion device 285 can comprise a plurality of thermophotovoltaic (TPV) cells 215 which receive the heated air 232 exiting the enclosed volume chamber 212. It can be appreciated that any known device can be used, for example, tubing and the like, to transfer the heated air 232 to the thermophotovoltaic cells 215. According to one design, the plurality of thermophotovoltaic cells 215 can be in the shape of a cone or a funnel, generally indicated as 290. The thermophotovoltaic cells 215 have a back surface 215a and a front surface 215b. The front surface 215b of the thermophotovoltaic cells 215 face an inside cavity, generally indicated as 291, of the cone or funnel 290. The heated air 232 applied to the thermophotovoltaic cells 215 can cause the cells 215 to become excited into DC electricity and the apparatus further includes a wiring system (not shown) associated with the thermophotovoltaic cells 215 for carrying the DC electricity to a target location for use. The apparatus 210 can further include at least one cooling tube 268 including coolant 276 extending about an outer surface 292 of the cone or funnel 290 and the back surface 215a of thermophotovoltaic cells for cooling the thermophotovoltaic cells 215. The coolant 276 can be cooling air or a cooling material, such as liquid nitrogen. It can be appreciated that more than one or more cooling tubes 268 or other cooling devices can be used to cool the cone or funnel 290 of thermophotovoltaic cells. It also can be appreciated that the thermophotovoltaic cells can have a different arrangement than the cone or funnel 290 shown in FIG. 2.

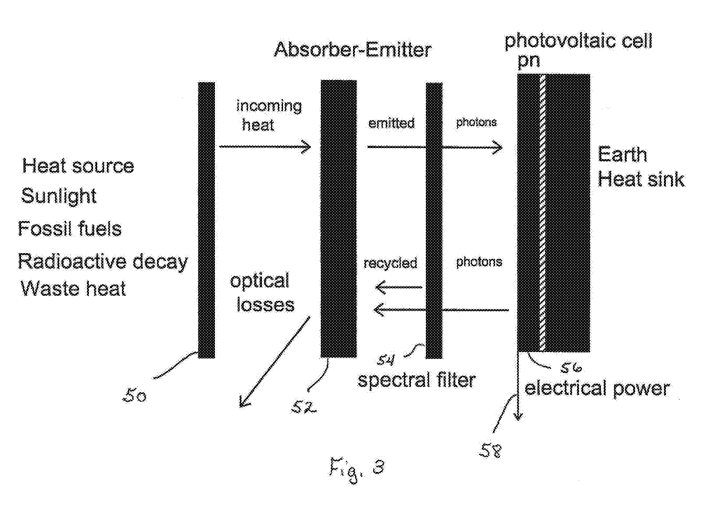

Reference is now made to FIG. 3, which shows a schematic representation of one example of a thermophotovoltaic cell which can be used in the solar energy converting apparatus 285 of the invention. Thermophotovoltaic systems convert heat energy into electricity via photons and consist of, at a minimum, an emitter and a photovoltaic cell power converter. However, most thermophotovoltaic systems include additional components, such as concentrators, filters, and reflectors. Thermophotovoltaic systems generate electricity by electromagnetic frequency at high temperatures and high frequencies. The basic principle of operation is similar to that of traditional photovoltaics where a p-n junction is used to absorb optical energy, generate and separate electron hold pairs, and in doing so, convert that energy into electrical power. As shown in FIG. 3, the thermophotovoltaic cell requires a heat source 50, which can be sunlight, fossil fuels, radioactive decay, waste heat, and the like. In the present invention, this heat source 50 is provided from the heated air 232 exiting the chamber 212. An absorber/emitter 52 is provided which absorbs the heat and emits or radiates the heat to a photovoltaic cell 56 via a spectral filter 54. The heat energy applied to the thermophotovoltaic cells 215 shown in FIG. 2 causes the cells to become excited and a wiring system, generally indicated as 58 in FIG. 3, can be associated with the photovoltaic cell 56 of the thermophotovoltaic cell 215 of FIG. 2 for converting the excited cells into DC electricity.

According to one embodiment, the thermophotovoltaic cells 215 can be formed from gallium antimonide or germanium; however, any known material can be used to form the thermophotovoltaic cells. These other materials include silicon, indium gallium arsenide antimonide, indium gallium arsenide, and indium phosphide arsenide antimonide.

Referring back to FIG. 1, the conversion device 285 can include a turbine 294 connected to a generator (not shown) for converting the heated air 232 exiting the enclosed volume chamber 212 into AC electricity and/or mechanical energy.

It can be appreciated that any stored or excess thermal energy can be fed to a second enclosed volume chamber and/or heat energy absorber, similar to the enclosed volume chamber 212 or heat absorber 220 as shown in FIG. 1, to enable this second enclosed volume chamber 212/heat absorber 220 to store this excess heat to maintain a predetermined level of heat energy in the enclosed volume chamber 212 and/or to provide a continuous heat source for the conversion devices 285.

The combination of the solar collecting chamber of FIG. 1 with the thermophotovoltaic cells of FIG. 2 and with the use of a turbine will enable one to exceed the 95% efficiency that Helmholtz called for as disclosed in detail in the previously referenced U.S. Pat. Nos. 7,640,931, 8,413,442, and 9,252,701.

Accordingly, the present invention is a clean energy, economically feasible system that is simple in design and operation, is self-sustainable, and can be used in combination with several types of conversion devices to convert the solar energy into electrical and/or mechanical energy in a continuous manner, twenty-four hours a day throughout the year. The invention achieves a desirable level of efficiency (almost 100%) which is obtainable through the use of smaller space requirements. Further still, the invention utilizes economically and readily available materials that collect, trap, and contain the solar energy within an enclosed volume chamber for conversion thereof into electrical and/or mechanical energy.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the invention. For example, it is to be understood that the present invention contemplates that, to the extent possible, one or more features of any embodiment can be combined with one or more features of any other embodiment.

1. An apparatus for storing and/or converting solar energy into a mechanical and/or electrical energy product, said apparatus comprising:
an enclosed volume chamber having a wall formed from transparent material capable of allowing solar energy beams to enter into the enclosed volume chamber, the wall of the enclosed volume chamber having a reflective inner surface for trapping and reflecting the solar energy beams within the enclosed volume chamber, wherein at least 50% of the wall of the enclosed volume chamber is formed from the transparent material that is capable of allowing solar energy beams to enter into the enclosed volume chamber and wherein the transparent material includes a reflective inner surface for trapping and reflecting the solar energy beams within the enclosed volume chamber;
a heat absorbing member located within the enclosed volume chamber for receiving at least a portion of the solar energy beams entering into and/or reflecting throughout the enclosed volume chamber;
at least one inlet for feeding air into the chamber wherein the air becomes heated;
at least one outlet for allowing the heated air to exit the chamber; and
a conversion device configured for cooperating with the outlet for receiving the heated air and for converting the heated air to mechanical and/or electrical energy.

2. The apparatus of claim 1, wherein the wall of transparent material comprises a one-way mirror.

3. The apparatus of claim 1, wherein the wall of transparent material comprises a high temperature glass and wherein the reflective inner surface facing an interior portion of the enclosed volume chamber comprises a mirrored surface or a reflective film.

4. The apparatus of claim 1, wherein the chamber includes an open space containing air located between an inner surface and the heat absorbing member, wherein the solar beams heat the air contained within the open space and the air fed into the enclosed volume chamber.

5. The apparatus of claim 1, wherein at least a portion of the air fed into the chamber is fed directly into the heat absorbing member.

6. The apparatus of claim 1, wherein more than 50% of the wall of the enclosed volume chamber is formed from the transparent material that is capable of allowing solar energy beams to enter into the enclosed volume chamber and includes a reflective inner surface for trapping and reflecting the solar energy beams within the enclosed volume chamber.

7. The apparatus of claim 1, wherein the transparent material is capable of withstanding temperatures of at least 900° C.

8. The apparatus of claim 1, wherein the enclosed volume chamber includes a mirrored floor surface configured to diffuse and reflect the solar energy beams.

9. The apparatus of claim 1, wherein the enclosed volume chamber is mounted on a base member and wherein a portion of the heat absorbing member is located within the base member.

10. The apparatus of claim 9, wherein the at least one inlet for feeding air into the chamber and the at least one outlet for allowing the heated air to exit the chamber is located within the portion of the heat absorbing member located within the base member.

11. The apparatus of claim 1, wherein the at least one inlet for feeding air into the chamber and the at least one outlet for allowing the heated air to exit the chamber is located within the wall of the enclosed volume chamber.

12. The apparatus of claim 1, wherein the enclosed volume chamber is in the shape of a dome.

13. The apparatus of claim 1, wherein the conversion device comprises a plurality of thermophotovoltaic cells which receive the heated air exiting the enclosed volume chamber.

14. The apparatus of claim 13, wherein the plurality of thermophotovoltaic cells are in the shape of a cone or a funnel and wherein thermophotovoltaic cells have a front surface facing an inside cavity of the cone or funnel.

15. The apparatus of claim 13, wherein the heated air applied to the thermophotovoltaic cells causes the cells to become excited into DC electricity and the apparatus further includes a wiring system associated with the thermophotovoltaic cells for carrying the DC electricity to a target location for use.

16. The apparatus of claim 14, including at least one cooling tube including coolant therein extending about an outer surface of the cone or funnel of thermophotovoltaic cells for cooling the thermophotovoltaic cells.

17. The apparatus of claim 1, wherein the conversion device includes a turbine connected to a generator for converting the heated air exiting the enclosed volume chamber into AC electricity.

18. The apparatus of claim 1, including at least one pump for feeding the air into the enclosed volume chamber.

19. The apparatus of claim 18, including a heat sensor for monitoring a temperature level of the enclosed volume chamber, said heat sensor being in communication with the at least one pump to increase or decrease the flow of air into the enclosed volume chamber in order to adjust the temperature within the enclosed volume chamber.

20. A system for collecting and converting solar energy into a mechanical and/or electrical energy product, said system comprising:
an enclosed volume chamber having a wall formed from transparent material capable of allowing solar energy beams to enter into the enclosed volume chamber, the wall of the enclosed volume chamber having a reflective inner surface for trapping and reflecting the solar energy beams within the enclosed volume chamber, wherein at least 50% of the wall of the enclosed volume chamber is formed from the transparent material;
a heat absorbing member located within the chamber for receiving at least a portion of the solar energy beams entering into and/or reflecting throughout the enclosed volume chamber;
at least one inlet for feeding air into the chamber wherein the air becomes heated;
at least one outlet for allowing the heated air to exit the chamber; and
at least one conversion device comprising at least one of a plurality of thermophotovoltaic cells and a turbine which convert the heated air into one of a mechanical and/or electrical energy product.
